(19) United States
(12) Patent Application Publication
(10) Pub. No.: US 2012/0253499 A1
(43) Pub. Date: Oct. 4, 2012

(54) COMPONENT MOUNTING DEVICE, INFORMATION PROCESSING DEVICE, INFORMATION PROCESSING METHOD, AND SUBSTRATE MANUFACTURING METHOD

(75) Inventor: Takeshi Nakamura, Saitama (JP)

(73) Assignee: SONY CORPORATION, Tokyo (JP)

(21) Appl. No.: 13/418,981

(22) Filed: Mar. 13, 2012

(30) Foreign Application Priority Data
Mar. 31, 2011 (JP) 2011-077982

(51) Int. Cl. H05K 13/02; H05K 13/04

(52) U.S. Cl. 700/121; 29/701

(57) ABSTRACT

A component mounting device which is provided with a plurality of feeders which contain a component, are able to store component information which is information which includes information on the type of the component which is contained, and supply each of the components for each type; an attaching section where each of the plurality of feeders is attached; a mounting unit which takes out each of the components from the plurality of feeders which are each attached in the attaching section and mounts the component which has been taken out on a substrate; and a control unit which executes a mounting process of the component using the mounting unit based on position information which is attaching position information for each of the plurality of feeders in the attaching section and the component information which is stored in each of the plurality of feeders.

### CROSS REFERENCES TO RELATED APPLICATIONS

The present application claims priority to Japanese Priority Patent Application JP 2011-077982 filed in the Japan Patent Office on Mar. 31, 2011, the entire content of which is hereby incorporated by reference.

### BACKGROUND

The present application relates to a component mounting device, an information processing device, an information processing method, and a substrate manufacturing method which mount a component on a substrate.

A component mounting device is typically a device in a head which takes out an electronic component by accessing a feeder which supplies the electronic component and mounts the electronic component on a circuit substrate or the like which is positioned in a region for mounting (for example, Japanese Unexamined Patent Application Publication No. 2005-166746)

In the component mounting device such as this, typically, an operator manually attaches a plurality of feeders on the component mounting device.

### SUMMARY

However, in a case where a phenomenon occurs such as where the operator makes an error in the attaching position of a feeder, there is a concern that the component mounting device takes out a component which is different to the component which is to be mounted and the component is mounted on the substrate. In addition, even if the component mounting device recognizes the error, the productivity of the product is reduced if the driving thereof is simply stopped.

It is desirable that a component mounting device, an information processing device, an information processing method, and a substrate manufacturing method are provided which are able to mount a component of a feeder on a substrate without stopping driving even in a case where the feeder which is to be attached is not attached in the predetermined position of an attaching section.

According to an embodiment of the present application, there is provided a component mounting device which includes a plurality of feeders, an attaching section, a mounting unit, and a control unit.

The plurality of feeders contain a component, are able to store component information which is information which includes information on the type of the component which is contained, and supplies each of the components for each type.

In the attaching section, each of the plurality of feeders is attached.

The mounting unit takes out each of the components from the plurality of feeders which are each attached in the attaching section and mounts the component which has been taken out on a substrate.

The control unit executes a mounting process of the component using the mounting unit based on position information which is attaching position information for each of the plurality of feeders in the attaching section and the component information which is stored in each of the plurality of feeders.

The control unit executes the mounting process based on the information on the attaching position of the feeder and the component information which is stored in the feeder which is attached in the attaching section. Accordingly, even in a case where the feeder which is to be attached is not attached in the predetermined position in the attaching section, the component mounting device is able to mount the component of the feeder on the substrate without stopping driving.

The control unit may acquire the position information of the attaching section and the component information from the plurality of feeders which are attached when the plurality of feeders are attached in the attaching section.

The control unit may acquire the position information of the attaching section and the component information from the plurality of feeders which are attached when the mounting unit takes out each of the components from the plurality of feeders.

The control unit may store correspondence information where the position information and the component information are made to correspond and execute the mounting process based on the correspondence information. Due to this, if the control unit acquires the component information from the plurality of filters once, after that, the process of acquiring the component information from the plurality of feeders is not necessary and it is possible to achieve efficiency of the processing time.

The control unit may calculate each of a fastest cycle time which is a cycle time where the mounting unit is able to execute the mounting process fastest and a current cycle time which is a cycle time of the mounting process which is necessary due to the current disposing of the plurality of feeders based on at least the position information and the component information. In this case, the control unit calculates the disposing information of the plurality of feeders in the attaching section which contributes to a shortening of the cycle time from the current cycle time based on the information on the fastest cycle time and the current cycle time. Due to this, it is possible for the control unit to present disposing information on the plurality of feeders which contributes to the shortening of the cycle time to an operator. Accordingly, the operator is able to perform redisposing of the feeders based on the disposing information.

The control unit may calculate the disposing information of the plurality of feeders in the attaching section which contributes to the shortening of the cycle time in a case where the difference of the fastest cycle time and the current cycle time exceeds a threshold. In a case where the difference is equal to or less than the threshold, it is possible to realize efficiency of the processing time in a case where the control unit executes the mounting process with the current disposing of the feeders as it is than, for example, a case where the redisposing of the feeders is performed.

The control unit may output information on redisposing of a portion of the feeders out of the calculated disposing information of the plurality of feeders in the attaching section which contributes to the shortening of the cycle time. Due to this, it is possible to easily perform redisposing of the feeders which is easily understood by the operator compared to a case where the calculated information on the redisposing of all of the feeders is presented once.

According to another embodiment of the present application, there is provided an information processing device which uses a component mounting device which includes a plurality of feeders, an attaching section, and a mounting unit and is provided with an acquisition section and a mounting process execution section.

The acquisition section acquires position information which is information on attaching positions of each of the plurality of feeders in the attaching section and component information which is stored in each of the plurality of feeders.

The mounting process execution section executes a mounting process of a component using the mounting unit based on the information which is acquired by the acquisition section.

According to still another embodiment of the present application, there is provided an information processing method which is executed by a component mounting device which includes a plurality of feeders, an attaching section, a mounting unit, and a control unit including the following.

Position information which is information on attaching positions of each of the plurality of feeders in the attaching section and component information which is stored in each of the plurality of feeders are acquired.

A mounting process of a component is executed using the mounting unit based on the information which is acquired.

According to still another embodiment of the present application, there is provided a substrate manufacturing method by a component mounting device which is provided with a plurality of feeders and an attaching section including the following.

Position information which is information on attaching positions of each of the plurality of feeders in the attaching section and component information which is stored in each of the plurality of feeders are acquired.

A component is taken out from each of the plurality of feeders which are each attached in the attaching section and the component which is taken out is mounted on a substrate.

Above, according to the embodiments of the present application, it is possible to mount the component of the feeder on the substrate without stopping driving even in a case where the feeder which is to be attached is not attached at the predetermined position in the attaching section.

Additional features and advantages are described herein, and will be apparent from the following Detailed Description and the figures.

### BRIEF DESCRIPTION OF THE FIGURES

FIG. 1 is a front surface diagram illustrating in a schematic manner a component mounting device according to a first embodiment of the present application;

FIG. 2 is a planar diagram of the component mounting device which is shown in FIG. 1;

FIG. 3 is a side surface diagram of the component mounting device which is shown in FIG. 1;

FIG. 4 is a block diagram illustrating a configuration of a control system of a component mounting device;

FIG. 5 is a flowchart illustrating actions according to the first embodiment of the present application;

FIG. 6 is a diagram for describing a process and is a diagram illustrating a correct disposing state of tape feeders;

FIG. 7 is a diagram for describing a process and is a diagram illustrating an erroneous disposing state of tape feeders;

FIG. 8 is a diagram illustrating correspondence information of at least component information and attaching information of tape feeders which contain components; and

FIG. 9 is a flowchart illustrating characteristic parts of actions according to a second embodiment of the present application.

### DETAILED DESCRIPTION

The present application is described below in further detail with reference to the drawings according to an embodiment.

### Configuration of Component Mounting Device

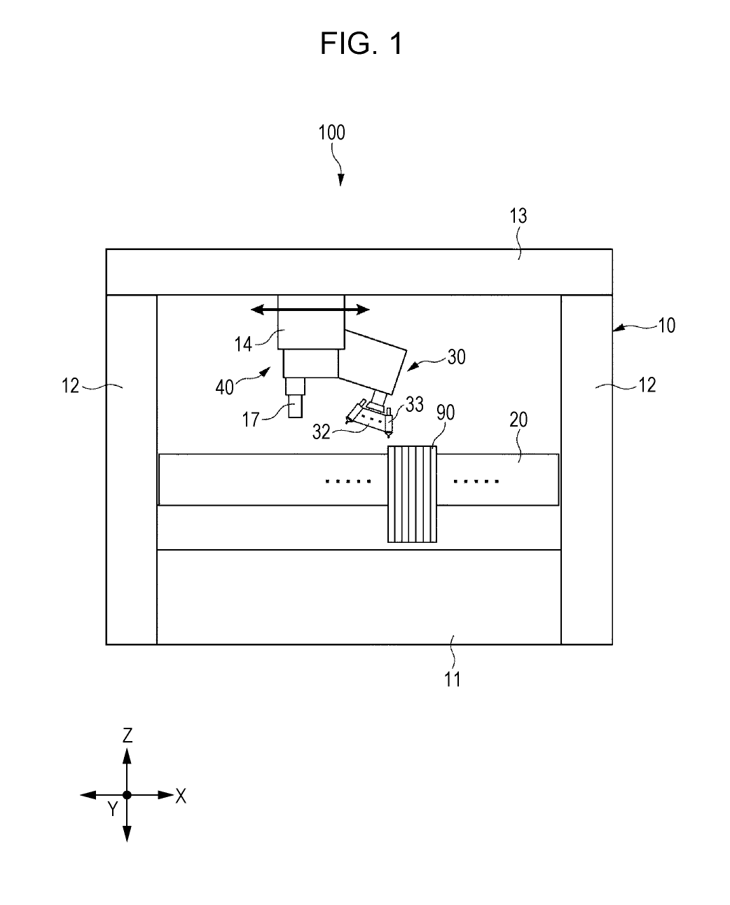

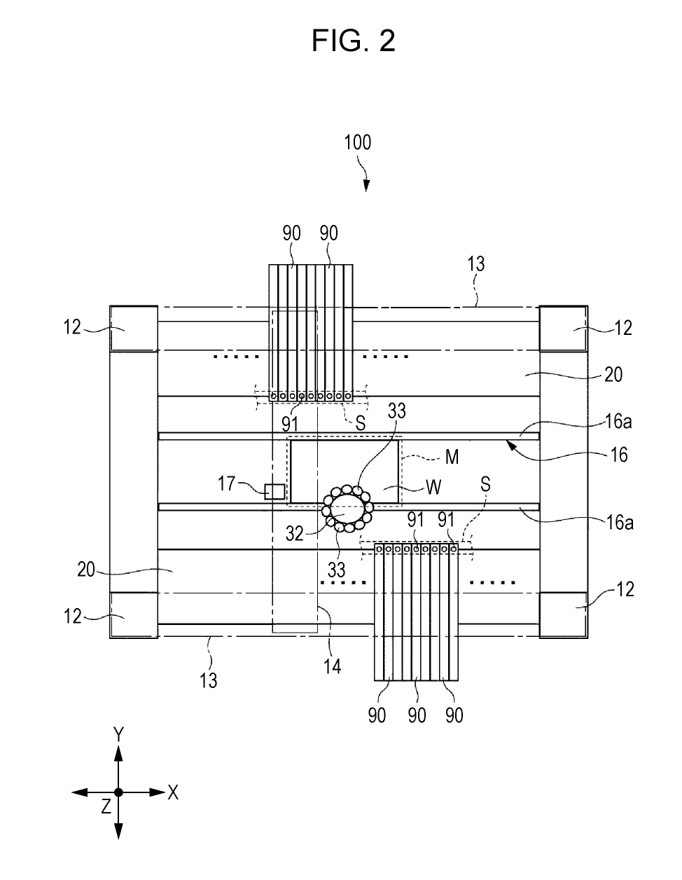

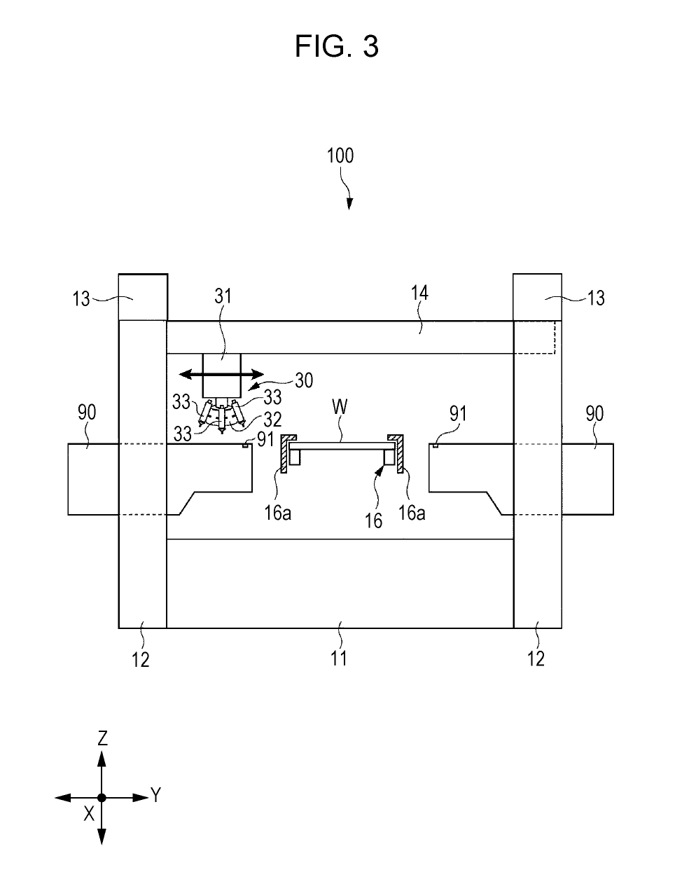

FIG. 1 is a front surface diagram illustrating in a schematic manner a component mounting device according to a first embodiment of the present application. FIG. 2 is a planar diagram of a component mounting device 100 which is shown in FIG. 1, and FIG. 3 is a side surface diagram thereof.

The component mounting device 100 is provided with a frame 10, a mounting head 30 which holds a component which is not shown and mounted the component on a circuit substrate (referred to below simply as a substrate) W which is a mounting target, an attaching section 20 where a tape feeder 90 is attached, and a transport unit 16 (refer to FIG. 2) which holds and transports the substrate W.

The frame 10 has a base 11 which is provided on a bottom portion and a plurality of supporting pillars 12 which are fixed to the base 11. In the upper portion of the plurality of supporting pillars 12, for example, two X beams 13 which span along the X axis in the diagram are provided. For example, between the two X beams 13, a Y beam 14 spans along the Y axis and the mounting head 30 is connected to the Y beam 14. In the X beams 13 and the Y beam 14, an X axis movement structure and a Y axis movement structure which are not shown are provided, and as such, it is possible for the mounting head 30 to move along the X axis and the Y axis. The X axis movement structure and the Y axis movement structure are typically configured using a ball screw driving structure, but other structures such as a belt driving structure may be used.

A mounting unit 40 is configured from the mounting head 30, the X axis movement structure, and the Y axis movement structure. There are cases where a plurality of the mounting units 40 are provided mainly in order to improve efficiency, and in this case, the plurality of mounting heads 30 are driven in the X and Y axial directions independently.

As shown in FIG. 2, the attaching section 20 is disposed on both the front portion side (lower side in FIG. 2) and the rear portion side (upper side in FIG. 2) of the component mounting device 100. The Y axial direction in the diagram is the front and back direction of the component mounting device 100. In the attaching section 20, a plurality of the tape feeders 90 are attached so as to line up along the X axial direction. For example, it is possible for 40 to 70 of the tape feeders 90 to be attached in the attaching section 20. In the embodiment, it is possible for 58 of the tape feeders 90 on each of the front portion and the rear portion, a total of 116, to be attached. It is possible for one of the tape feeders 90 to contain, for example, approximately 100 to 10000 of the electronic components.

Here, the attaching section 20 is configured to be provided on both the front edge side and the rear edge side of the component mounting device 100, but the attaching section 20 may be configured to be provided on either one the front edge side or the rear edge side.

The taper feeder 90 is formed to be long in the Y axial direction and is a cassette type feeder. The details of the tape feeder 90 are not shown in the diagram, but a reel is provided and carrier tape which contains an electronic component such as a condenser, a resistor, an LED, or an IC packaging is wound on the reel. In addition, the tape feeder 90 is provided with a structure for feeding out the carrier tape by step feeding and the electronic components are supplied one at a time for each of the step feeds.

As shown in FIG. 2, a supply window 91 is formed in the upper surface of the edge portion of a cassette of the tape feeder 90 and the electronic component is supplied via the supply window 91. A region where a plurality of the supply windows 91 are each disposed, which is formed along the X axial direction due to the plurality of tape feeders 90 being lined up, is an electronic component supply region S. That is, a plurality of the supply regions S is lined up in a straight line along the transport direction of the substrate W.

The transport unit 16 described above is provided in the central portion of the component mounting device 100 in the Y axial direction and the transport unit 16 transports the substrate W along the X axial direction. For example, as shown in FIG. 2, a region which is disposed on the substrate W, which is supported by the transport unit 16 in substantially the central portion on the transport unit 16 in the X axial direction, is a mounting region M where the mounting of the electronic component is performed due to accessing by the mounting head 30.

The mounting head 30 is provided with a carriage 31 which is connected to the Y axis movement structure of the Y beam 14, a turret 32 which is provided so as to extend diagonally downward from the carriage 31, and a plurality of suction nozzles 33 which is attached along the circumference direction of the turret 32. The suction nozzles 33 take out and hold the electronic component from the carrier tape due to a vacuum suction action. The suction nozzles 33 are able to move up and down so as to mount the electronic component on the substrate W. For example, 12 of the suction nozzles 33 are provided.

The mounting head 30 is able to move in the X and Y axial directions as described above, the suction nozzles 33 move between the supply region S and the mounting region M, and in addition, moves in the X and Y axial directions in the mounting region M so as to execute the mounting in the mounting region M.

The turret 32 is able to rotate (spin) with a shaft in a diagonal direction as the central rotation shaft. The suction nozzles 33 which are disposed so that the length direction of the suction nozzles 33 is along the Z direction out of the plurality of suction nozzles 33 are the suction nozzles 33 which are selected for mounting the electronic component on the substrate W. An arbitrary one of the suction nozzles 33 is selected using the rotation of the turret 32. The electronic component is suction and held by the suction nozzles 33 which have been selected accessing the supply window 91 of the tape feeder 90 and the electronic components are mounted on the substrate W by being moved and lowered to the mounting region M.

The mounting head 30 holds each of a plurality of the electronic components continuously in one process with the plurality of suction nozzles 33 while the turret 32 rotates. In addition, the electronic components which are suctioned by the plurality of suction nozzles 33 are mounted on one substrate W continuously in one process.

As shown in FIG. 1, the substrate camera 17 which detects the position of the substrate W is attached in the mounting head 30. The substrate camera 17 is able to move integrally with the mounting head 30 using the X axis and Y axis movement structures. The substrate camera 17 is disposed on an upper portion of the transport unit 16 and images an image of the substrate W from the upper portion side when the position of the substrate W is detected. The substrate camera 17 recognizes an alignment mark which is provided on the substrate W and the mounting unit 40 mounts the electronic component on the substrate W with the alignment mark as the reference position.

The transport unit 16 is typically a belt type of conveyer, but is not limited to this and any be any of a roller type, a type where a support mechanism which supports the substrate W moves by sliding, a non-contact type, or the like. The transport unit has a guide rail 16a which is provided along the X axial direction. Due to this, there is transportation with deviation in the Y axial direction of the substrate W which is transported being regulated.

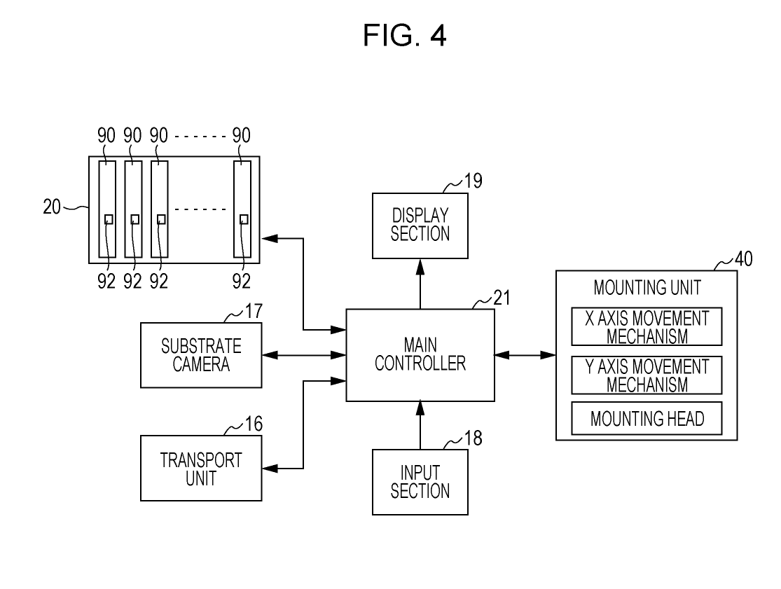

FIG. 4 is a block diagram illustrating a configuration of a control system of the component mounting device 100.

The control system has a main controller 21 (or a host computer). In the main controller 21, the attaching section 20, the tape feeder 90, the substrate camera 17, the transport unit 16, the mounting unit 40, an input section 18, and a display section 19 are electrically connected.

In each of the movement structures and the mounting head 30 of the mounting unit 40, motors (not shown) which are installed therein and drivers which drive each of the motors are provided. The drivers drive each of the movement structures and the mounting head 30 according to control signals due to the main controller 21 outputting the control signals to the drivers.

The input section 18 is a device which, for example, is operated by the operator for the operator to input information which is necessary for the mounting process to the main controller 21.

The information which is necessary for the mounting process is, for example, information which relates to the substrate which is the mounting target from here, identification information (tape feeder ID) which identifies each of the tape feeders 90 which are to be attached or which are attached in the attaching section 20, and the like. In the tape feeder identification information, the component information, the tape information, and the like which are described later are made to correspond.

The information which relates to the substrate is, in other words, information which relates to the substrate product. In the information, information on the type of the substrate which is the mounting target (shape of the substrate and the like) and information on the type, number and the like of the components which are necessary for the substrate.

In one of the attaching sections 20 out of the two in the front and back, for example, a total of 58 connection sections which are not shown are lined up in the tape feeder 90 as described above. The tape feeders 90 are able to be attached to the attaching section 20 by each being connected for each of the connection sections. When the tape feeders 90 are connected to the connection section, the main controller 21 is able to electrically recognize that the tape feeder 90 is connected to the connection section in which position (in which order) out of the attaching section 20.

The display section 19 is a device which, for example, displays information which is input via the input section 18 by the operator, information which is necessary for the input operation, and other information which is necessary.

The main controller 21 has, for example, a function of a computer such as a CPU, a RAM, and a ROM and functions as a control unit. The main controller 21 may be realized by a device such as a PLD (Programmable Logic Device) such as a FPGA (Field Programmable Gate Array) or another ASIC (Application Specific Integrated Circuit).

In one of the carrier tapes of the tape feeder 90, a plurality of the same electronic components is contained. The same component is, in other words, the same type of component, for example, an “50 pF condenser” or the like. If the capacity of the condensers is different, the condensers are different components. Out of the tape feeders 90 which are installed in the attached section 20, there are cases where the same electronic component is contained over a plurality of tape feeders 90.

The tape feed 90 has a memory 92. The memory 92 is electrically connected to the main controller 21 by the tape feeder 90 being set so as to be connected to the connection section of the attaching section 20. In the memory 92, information which relates to the tape feeder is stored. In the information which relates to the tape feeder, information on the electronic component which is contained in the tape feeder 90 (referred to below as the component information) and the tape information is included.

In the component information, at least information on the type of the component such as an “50 pF condenser” or the like as described above is included.

In the tape information, for example, information such as the length of the tape, the number of components contained, the pitch at which the components are contained, and the like are included.

### Actions of First Embodiment of Component Mounting Device (Substrate Manufacturing Method)

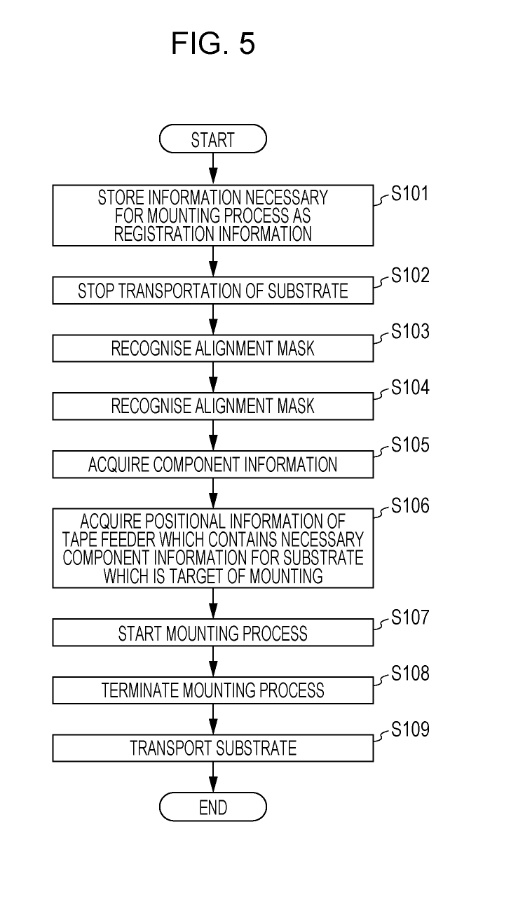

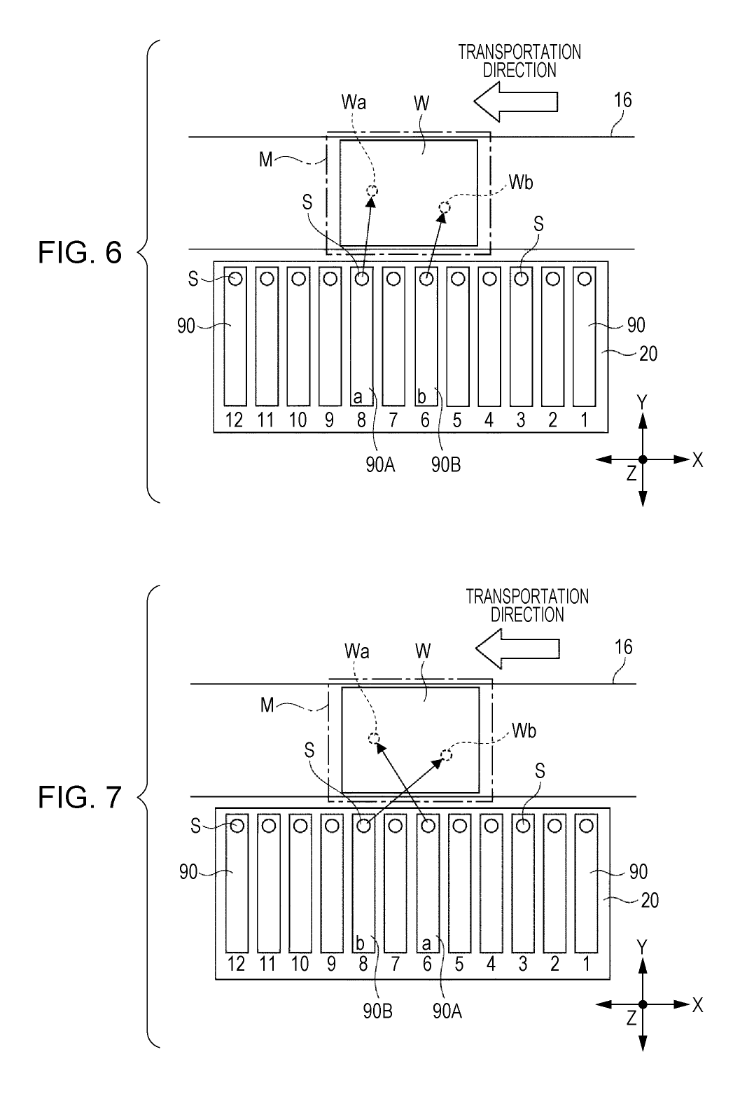

FIG. 5 is a flowchart illustrating actions according to the first embodiment of the component mounting device 100 and is a flowchart illustrating mainly the process of the main controller 21. FIGS. 6 and 7 are diagrams for describing this process. In FIG. 6, the number of tape feeders which are lined up by being attached in the attaching section 20 is shown as 12 in order for simplification of the diagram.

Before the activating of the component mounting device 100, the operator inputs information which relates to the substrate W which is the mounting target as described above to the main controller 21 via the input section 18.

Due to this, the main controller 21 stores the component information, the number of components, and the like which is necessary for the substrate W as registration information (step S101). Then, the main controller 21 presents the identification information of the necessary tape feeder 90 according to the registration information, the information on the position of the tape feeder 90 in the attaching section 20, and the like are presented in the display section 19. The information which is presented in the main controller 21 at this time is disposing information of the tape feeders 90 in the attaching section 20 where it is possible for the mounting unit 40 to execute the mounting process with the fastest cycle time.

That is, in FIG. 6, the main controller 21 has information which is to dispose the tape feeder 90, which contains the component which is necessary for the substrate W which is the current mounting target here, in a position (connection section) out of No. 1 to 12 of the attaching sections 20.

The fastest cycle time is the cycle time when the total of the movement distance between the supply region S and the mounting region M of the mounting head 30 is the smallest.

According to the information which is displayed, the operator attaches the plurality of tape feeders 90 to predetermined positions in the attaching section 20.

As an example, FIG. 6 illustrates the disposing state of the original tape feeder 90 where the mounting process is executed with the fastest cycle time which is presented by the main controller 21 based on the registration information. Here, the components which are necessary for the substrate W which is the mounting target is at least components a and b. Then, in order to realize the fastest cycle time, a tape feeder 90A and a tape feeder 90B which respectively contain the components a and b are to be attached in No. 8 and 6 of the attaching section 20. The components a and b are to be respectively mounted in each of the mounting points Wa and Wb in the substrate W.

However, as shown in FIG. 7, in practice, the operator has made an error in at least the attaching positions of the tape feeders 90A and 90B and the tape feeder 90A is attached in the position of No. 6 and the tape feeder 90B is attached in the position of No. 8. In this case, the movement distance of the mounting head 30 is longer compared to the case shown in FIG. 6 and the cycle time is longer. However, the characteristic of the embodiment is that the component mounting device 100 executes the mounting process in a tape feeder 90 attaching state such as this. This is described below.

When the substrate is transported until the mounting region M, the main controller 21 stops the transport of the substrate W due to the transport unit 16 (step S102).

The main controller 21 recognizes the alignment mark which is provided in a predetermined position on the substrate W using the substrate camera 17 (step S103).

When the alignment mark is recognized, the main controller 21 calculates a reference position (reference coordinates) when performing the mounting process by moving the movement head 30 which corresponds to the substrate W which is the mounting target (step S104).

The main controller 21 acquires the component information from all of the tape feeders 90 which are attached in the attaching section 20 and stores the component information (step S105). In this case, the main controller 21 mainly functions as the acquisition section of the information processing device.

The main controller 21 recognizes the component information which corresponds to the components which are necessary for the substrate W which is the mounting target based on the registration information. Then, the main controller 21 searches for the position in the attaching section 20 where the tape feeder 90 which has the component information which is necessary for the substrate W is attached and acquires the information on the attaching position (step S106). Here, the information on the attaching position is position information which is the lining up position of the tape feeder 90 in the transport direction (the X axial direction) of the substrate W in the attaching section 20, that is, which in the ordering of the positions (which in the ordering of the connection sections) in the transport direction out of No. 1 to 12.

In this manner, it is possible for the actual attaching position to be recognized even when there is an error in the attaching position of the tape feeder 90 due to the operator by the main controller 21 acquiring the information on the actual attaching position of the tape feeder 90 which contains the component.

Here, it is possible for the actual attaching position of the tape feeder 90 to be recognized using the connection section which connects the tape feeder 90 as described above.

In step S106, the main controller 21 may acquire the component position which is necessary for the substrate W and information on the attaching position of the tape feeder 90 which has this component information when the mounting head 30 takes out the component from the supply region S.

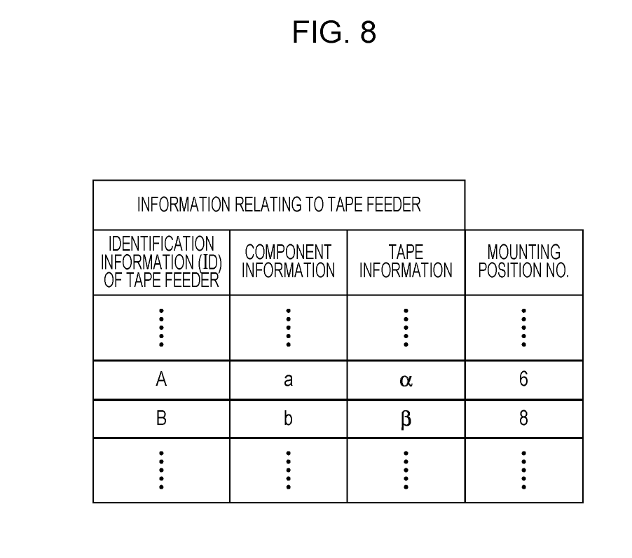

Alternatively, after acquiring the component information and the information on the attaching position which corresponds to the component information once, the main controller 21 may store at least correspondence information 50 of this information and may use the correspondence information as a lookup table as shown in FIG. 8. Due to this, it is not necessary for this information to be acquired for each process of the mounting head 30 taking out the component from the component and it is possible to improve the efficiency of the processing time. A lookup table in FIG. 8 may be formed for each substrate which is the current mounting target and the table with regard to the plurality of types of substrates may be formed as a list.

Alternatively, the main controller 21 may store the correspondence information by acquiring the information on the component information and the attaching position which corresponds to this at a point in time where the operator actually attaches the tape feeder 90 to the attaching section 20.

The main controller 21 executes the mounting process using the mounting unit 40 based on the component information and the information on the attaching position (step S107). In this case, the main controller 21 mainly functions as the mounting position execution section of the information processing device.

Here, the main controller 21 correctly mounts the components a and b respectively in the mounting points Wa and Wb as shown in FIG. 7 even when the actual attaching positions of the tape feeder 90A and the tape feeder 90B are erroneous by acquiring the component information necessary for the substrate W and the information on the attaching position of the tape feeder 90 which has these components.

As a result, for example, the productivity of the product is improved since it is possible for the component mounting device 100 to execute the mounting process without stopping driving.

In addition, as a reference example which is contrasted with the present application, for example, there is a phenomenon where the component a is mounted in the mounting point Wb and the component b is mounted in the mounting point Wa in a case where the component mounting device does not stop the driving even if there is an error in the attaching position. In this case, the components and the substrate are discarded. However, according to the embodiment of the present application, it is possible for this phenomenon to be prevented and it is possible for waste of the components and the substrate to be prevented.

When the components which are necessary are all mounted on the substrate W (step S108), the substrate W is transported using the driving of the transport unit 16 (step S109).

Here, in the case where the production of other types of the substrate W is performed, for example, the operator stops the driving of the component mounting device 100, information which is necessary for a new mounting process is registered (“step rearranging” is performed), and the main controller 21 repeats the processes which are shown in FIG. 5.

### Actions of Component Mounting Device of Second Embodiment

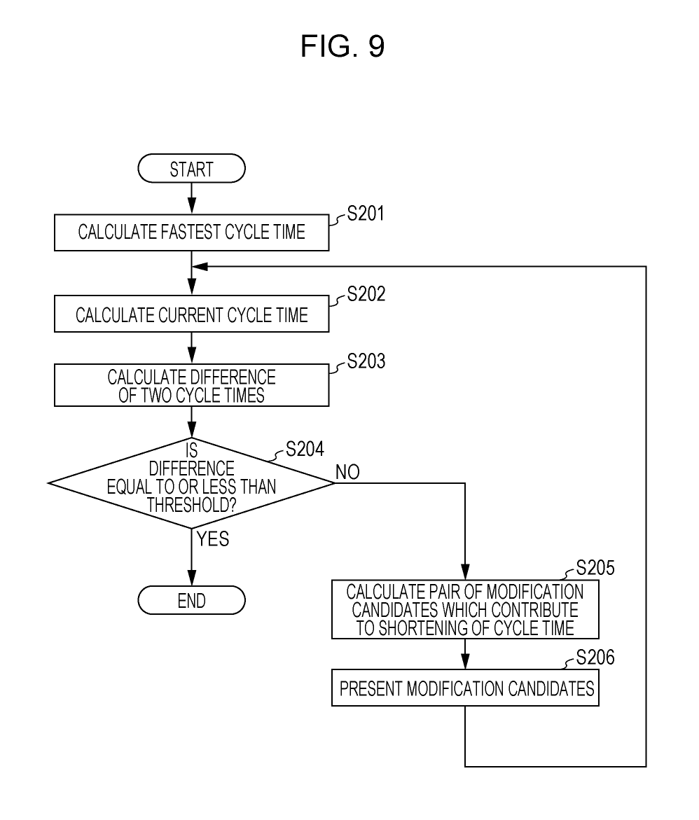

FIG. 9 is a flowchart illustrating characteristic parts of actions according to the component mounting device 100 of a second embodiment and is mainly a flowchart illustrating the processing of the main controller 21.

In the processing according to the second embodiment, the main processing according to the first embodiment described above is included. Accordingly, in the embodiment, there is described with the portions which are different to the first embodiment described above as key points. The main controller 21 is able to execute the process shown in FIG. 9 at an appropriate time, for example, after step S101 of FIG. 5, and for example, may execute after step S108 or S109.

The main controller 21 calculates the fastest cycle time which is the cycle time where the mounting unit 40 is able to execute the mounting process fastest (step S201). That is, the fastest cycle time is, for example, a cycle time of the mounting head 30 when the total of the movement distance of the supply region S and the mounting region M is the smallest. The main controller 21 is able to calculate the fastest cycle time based on at least the registration information which is input by the operator, that is, the information which relates to the substrate (the information on the type of substrate, the type, number, and the like of the components which are necessary for the substrate).

The main controller 21 calculates the current cycle time which is the cycle time of the mounting process due to the disposing of the current tape feeder 90 (step S202). For example, the main controller 21 calculates the current cycle time based on the information which relates to the substrate, the component information which has been acquired, and the information on the attaching position.

The main controller 21 calculates the difference of the fastest cycle time and the current cycle time which has been calculated (step S203).

The main controller 21 determines whether or not the difference which has been calculated exceeds a threshold (step S204). In a case where the difference is equal to or less than the threshold, the mounting process continues in a state of the current actual disposing of the tape feeders.

The main controller 21 calculates the disposing information of each of the tape feeders 90 in the attaching section 20 which contributes to the shortening of the cycle time from the current cycle time in a case where the difference exceeds the threshold. Then, the main controller 21 extracts modification candidates which is information of the redisposing of a portion of the attaching positions, typically, an exchange candidate of a pair of the attaching positions, out of all of the tape feeders 90 which contributes to the shortening of the cycle time using the calculation of the disposing information (step S205).

For example, it is possible to shorten the current cycle time by setting a disposing state such as in FIG. 6 by exchanging the pair of the tape feeder 90A and the tape feeder 90B shown in FIG. 7.

The main controller 21 presents the information on the pair of modification candidates which have been extracted (step S206). For example, the main controller 21 outputs the information on the modification candidates to the display section 19 or outputs to a terminal unit which is carried by the operator. Due to this, the operator is able to exchange the disposing of the tape feeders 90 according to the pair of modification candidates by temporarily stopping the driving of the component mounting device 100 or the like.

The main controller 21 is able to acquire the disposing state of the fastest cycle time after step S206 by repeating the processes from step S202.

In the embodiment, since the information on the pair of modification candidates is presented in this manner, it is possible to easily perform exchanging of the tape feeder 90 which is easily understood by the operator compared to a case where information on the redisposing of all of the tape feeders which has been calculated is presented at one time.

In the embodiment, in a case where the difference is equal to or less than the threshold in the determining process of step S204, it is possible to realize efficiency in the processing time in a case where the mounting unit 40 executes the mounting process with the current disposing of the tape feeders 90 as it is rather than a case where the redisposing of the tape feeders 90 is performed.

For example, the present application is effective even in a case where the arrangement order of the tape feeders 90 is correct but the operator attaches the attaching positions of the tape feeders 90 in the attaching section 20 as being deviated by one before the driving of the component mounting device 100. In this case, this is because the processing time is not necessary when the mounting process is performed with the disposing state of the tape feeders 90 which are erroneous as it is rather than the operator redisposing by deviating the attaching positions of the tape feeders 90 one by one. The characteristic effects of the embodiment such as this are the same as the first embodiment described above.

The threshold in the determination process of step S204 may be a predetermined constant value or may be determined in a variable manner. In the case of the threshold being determined in a variable manner, for example, a plurality of predetermined values may be prepared or the main controller 21 may calculate the threshold using a predetermined calculation equation.

The predetermined calculation equation may be, for example, a calculation equation based on the remaining number of components which are to be mounted on the substrate W in the current mounting process or a calculation equation based on the following number of substrates W which are mounting targets which are the same as the substrate W in the current mounting process.

In the description described above, the main controller 21 extracts a pair of modification candidates but modifications of the disposing of three or more of the tape feeders 90 may be extracted. Alternatively, the main controller 21 may present a plurality of pairs of modification candidates in a list in order from the pairs which are closest to the fastest cycle time.

Alternatively, the following process may be executed in a case where, for example, the number of the remaining components which exist in the attaching section 20 is small and is equal to or less than a threshold. In this case, if there is a location (connection section) which is available in the attaching section 20, the main controller 21 may present so that the tape feeder 90 which contains the component is set in the location which is available. The presentation means may use the display section 19, a terminal unit, or the like as described above. Then, after the operator attaches the tape feeder 90 to the location which is available, the main controller 21 may execute the process shown in FIG. 9.

### Other Embodiments

The present application is not limited to the embodiment described above and other various embodiments are able to be realized.

In the embodiment described above, it is possible for the plurality of tape feeders 90 to be attached in the attaching section 20 along the transport direction of the substrate W. However, the present application is not limited to this and there may be a format where the tape feeders 90 are lined up in a direction which is orthogonal to the transport direction in the horizontal plane (in the X-Y plane) in the attaching section or there may be a format where the tape feeders 90 are lined up in the vertical direction (Z direction). Alternatively, there may be a format where the tape feeders 90 are lined up in a diagonal direction other than this. Alternatively, there may be a format where the tape feeders are lined up along a curved direction which is circular, arced, or the like without being limited to being linear. In these cases, the main controller 21 also executes the mounting process by acquiring the position information of each tape feeder.

The mounting head 30 is provided with the turret 32 which rotates and the plurality of suction nozzles 33. However, the mounting head may have only one suction nozzle. Alternatively, the mounting head may not have the turret which rotates and may be a linear type where a plurality of suction nozzles which are lined up in a linear manner.

Out of the characteristic sections of each of the embodiments which are described above, it is possible for at least two of the characteristic sections to be combined.

It is possible for the present application to be configured as below.

(1) A component mounting device which is provided with a plurality of feeders which contain a component, are able to store component information which is information which includes information on the type of the component which is contained, and supply each of the components for each type, an attaching section where each of the plurality of feeders is attached, a mounting unit which takes out each of the components from the plurality of feeders which are each attached in the attaching section and mounts the component which has been taken out on a substrate, and a control unit which executes a mounting process of the component using the mounting unit based on position information which is attaching position information for each of the plurality of feeders in the attaching section and the component information which is stored in each of the plurality of feeders.

(2) The component mounting device described in (1) where the control unit acquires the component information from the plurality of feeders which are attached in the attaching section when the plurality of feeders are attached in the attaching section.

(3) The component mounting device described in (1) where the control unit acquires the position information of the attaching section and the component information from the plurality of feeders which are attached when the mounting unit takes out each of the components from the plurality of feeders.

(4) The component mounting device described in one out of any of (1) to (3) where the control unit stores correspondence information where the position information and the component information are made to correspond and executes the mounting process based on the correspondence information.

(5) The component mounting device described in one out of any of (1) to (4) where the control unit calculates each of a fastest cycle time which is a cycle time where the mounting unit is able to execute the mounting process fastest and a current cycle time which is a cycle time of the mounting process which is necessary due to the current disposing of the plurality of feeders based on at least the position information and the component information and calculates the disposing information of the plurality of feeders in the attaching section which contributes to a shortening of the cycle time from the current cycle time based on the information on the fastest cycle time and the current cycle time.

(6) The component mounting device described in (5) where the control unit calculates the disposing information of the plurality of feeders in the attaching section which contributes to the shortening of the cycle time in a case where the difference of the fastest cycle time and the current cycle time exceeds a threshold.

(7) The component mounting device described in (5) or (6) where the control unit outputs information on redisposing of a portion of the feeders out of the calculated disposing information of the plurality of feeders in the attaching section which contributes to the shortening of the cycle time.

(8) An information processing device, which uses a component mounting device which includes a plurality of feeders which contain a component, are able to store component information which is information which includes information on the type of the component which is contained, and supply each of the components for each type, an attaching section where each of the plurality of feeders is attached, and a mounting unit which takes out each of the components from the plurality of feeders which are each attached in the attaching section and mounts the component which has been taken out on a substrate, which is provided with an acquisition section acquires position information which is information on attaching positions of each of the plurality of feeders in the attaching section and component information which is stored in each of the plurality of feeders, and a mounting process execution section executes a mounting process of a component using the mounting unit based on the information which is acquired by the acquisition section.

(9) An information processing method, which is executed by a component mounting device which includes a plurality of feeders which contain a component, are able to store component information which is information which includes information on the type of the component which is contained, and supply each of the components for each type, an attaching section where each of the plurality of feeders is attached, and a mounting unit which takes out each of the components from the plurality of feeders which are each attached in the attaching section and mounts the component which has been taken out on a substrate, including acquiring position information which is information on attaching positions of each of the plurality of feeders in the attaching section and component information which is stored in each of the plurality of feeders, and executing a mounting process of a component using the mounting unit based on the information which is acquired.

(10) A substrate manufacturing method, which is executed by a component mounting device which includes a plurality of feeders which contain a component, are able to store component information which is information which includes information on the type of the component which is contained, and supply each of the components for each type, and an attaching section where each of the plurality of feeders is attached, including acquiring position information which is information on attaching positions of each of the plurality of feeders in the attaching section and component information which is stored in each of the plurality of feeders, and taking out a component from each of the plurality of feeders which are each attached in the attaching section and mounting the component which is taken out on a substrate.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A component mounting device comprising:
a plurality of feeders which contain a component, are able to store component information which is information which includes information on the type of the component which is contained, and supply each of the components for each type;
an attaching section where each of the plurality of feeders is attached;
a mounting unit which takes out each of the components from the plurality of feeders which are each attached in the attaching section and mounts the component which has been taken out on a substrate; and
a control unit which executes a mounting process of the component using the mounting unit based on position information which is attaching position information for each of the plurality of feeders in the attaching section and the component information which is stored in each of the plurality of feeders.

2. The component mounting device according to claim 1,
wherein the control unit calculates each of a fastest cycle time which is a cycle time where the mounting unit is able to execute the mounting process fastest and a current cycle time which is a cycle time of the mounting process which is necessary due to the current disposing of the plurality of feeders based on at least the position information and the component information and calculates the disposing information of the plurality of feeders in the attaching section which contributes to a shortening of the cycle time from the current cycle time based on the information on the fastest cycle time and the current cycle time.

3. The component mounting device according to claim 2,
wherein the control unit calculates the disposing information of the plurality of feeders in the attaching section which contributes to the shortening of the cycle time in a case where the difference of the fastest cycle time and the current cycle time exceeds a threshold.

4. The component mounting device according to claim 2,
wherein the control unit outputs information on redisposing of a portion of the feeders out of the calculated disposing information of the plurality of feeders in the attaching section which contributes to the shortening of the cycle time.

5. The component mounting device according to claim 1,
wherein the control unit acquires the component information from the plurality of feeders which are attached in the attaching section when the plurality of feeders are attached in the attaching section.

6. The component mounting device according to claim 1,
wherein the control unit acquires the position information of the attaching section and the component information from the plurality of feeders which are attached when the mounting unit takes out each of the components from the plurality of feeders.

7. The component mounting device according to claim 1,
wherein the control unit stores correspondence information where the position information and the component information are made to correspond and executes the mounting process based on the correspondence information.

8. An information processing device which uses a component mounting device, which includes a plurality of feeders which contain a component, are able to store component information which is information which includes information on the type of the component which is contained, and supply each of the components for each type, an attaching section where each of the plurality of feeders is attached, and a mounting unit which takes out each of the components from the plurality of feeders which are each attached in the attaching section and mounts the component which has been taken out on a substrate, the device comprising:
an acquisition section which acquires position information which is information on attaching positions of each of the plurality of feeders in the attaching section and component information which is stored in each of the plurality of feeders; and
a mounting process execution section which executes a mounting process of a component using the mounting unit based on the information which is acquired by the acquisition section.

9. An information processing method, which is executed by a component mounting device which includes a plurality of feeders which contain a component, which are able to store component information which is information which includes information on the type of the component which is contained, and supply each of the components for each type, an attaching section where each of the plurality of feeders is attached, and a mounting unit which takes out each of the components from the plurality of feeders which are each attached in the attaching section and mounts the component which has been taken out on a substrate, the method comprising:
acquiring position information which is information on attaching positions of each of the plurality of feeders in the attaching section and component information which is stored in each of the plurality of feeders; and
executing a mounting process of a component using the mounting unit based on the information which is acquired.

10. A substrate manufacturing method, which is executed by a component mounting device which includes a plurality of feeders which contain a component, are able to store component information which is information which includes information on the type of the component which is contained, and supply each of the components for each type, and an attaching section where each of the plurality of feeders is attached, the method comprising:
acquiring position information which is information on attaching positions of each of the plurality of feeders in the attaching section and component information which is stored in each of the plurality of feeders; and
taking out a component from each of the plurality of feeders which are each attached in the attaching section and mounting the component which is taken out on a substrate.
